(19) United States
(12) Patent Application Publication
(10) Pub. No.: US 2023/0040738 A1
(43) Pub. Date: Feb. 9, 2023

(54) POLISHING COMPOSITION

(71) Applicant: JAPAN VAM & POVAL CO., LTD., Osaka (JP)

(72) Inventors: Takashi MURAKAMI, Osaka (JP); Yoshihiro KIMURA, Osaka (JP)

(73) Assignee: JAPAN VAM & POVAL CO., LTD., Osaka (JP)

(21) Appl. No.: 17/793,264

(22) PCT Filed: Jan. 22, 2021
(86) PCT No.: PCT/JP2021/002201

§ 371 Date: Jul. 15, 2022

(30) Foreign Application Priority Data
Jan. 22, 2020 (JP) 2020-008078
Feb. 20, 2020 (JP) 2020-027613

(51) Int. Cl. C09G 1/02

(52) U.S. Cl. CPC C09G 1/02

(57) ABSTRACT

Provided is a novel polishing composition. The polishing composition comprises a water-soluble polymer that at least comprises a vinyl alcohol-based resin of which a 4% aqueous solution has a viscosity of 15 mPa·s or more at 20° C.

### TECHNICAL FIELD

The present invention relates to a novel polishing composition etc.

### BACKGROUND ART

The surface of silicon wafers, which are used as components of semiconductor devices etc., is generally polished to a high-quality mirror finish through a lapping step (rough polishing step) and a polishing step (precision polishing step). The polishing step typically includes a primary polishing substep and a final polishing substep.

The polishing step uses polishing compositions.

Polishing compositions comprising water-soluble polymers are known. For example, Patent Literature 1 describes a polishing composition comprising hydroxyethyl cellulose and/or polyvinyl alcohol and a blocked polyether.

In addition, Patent Literature 2 discloses a semiconductor wetting agent comprising a water-soluble polymer (hydroxyethyl cellulose, polyvinyl alcohol, polyvinylpyrrolidone, etc.) of which a 0.3 wt % aqueous solution has a viscosity of less than 10 mPa·s at 25° C.

### CITATION LIST

### Patent Literature

Patent Literature 1: JP-A 2005-85858
Patent Literature 2: JP-A 2010-34509

### SUMMARY OF INVENTION

### Technical Problem

An object of the present invention is to provide a novel polishing composition.

Another object of the present invention is to provide a polishing composition that can be used for polishing, in particular, semiconductor substrates such as silicon wafers, to achieve a reduced roughness as measured by atomic force microscopy (AFM roughness) on the polished surface.

Another object of the present invention is to provide a polishing composition that can be used for polishing the aforementioned substrates to achieve a reduced haze on the polished surface.

Yet another object of the present invention is to provide a method for producing a polished product using such a polishing composition.

### Solution to Problem

The present inventors focused on AFM roughness on the polished surface of substrates such as semiconductor substrates and found that when a polishing composition comprising a water-soluble polymer was used for polishing the surface of semiconductor substrates, some types of water-soluble polymers were attributed to higher AFM roughness on the polished surface.

After conducting extensive research to solve the above problem, the present inventors found that a polishing composition comprising a specific water-soluble polymer and other components can be used for polishing semiconductor substrates to achieve a reduced AFM roughness on the polished surface.

That is, the present invention relates to the following.

[1] A polishing composition comprising a water-soluble polymer, wherein the water-soluble polymer at least comprises a vinyl alcohol-based resin, and wherein a 4% aqueous solution of the vinyl alcohol-based resin has a viscosity of 15 mPa·s or more at 20° C.
[2] The polishing composition according to the above [1], wherein the water-soluble polymer has a saponification value of 80 to 99.9 mol %.
[3] The polishing composition according to the above [1] or [2], further comprising abrasive grains.
[4] The polishing composition according to the above [3], wherein the abrasive grains comprise silica.
[5] The polishing composition according to any one of the above [1] to [4], wherein the amount of monomers having an acid group relative to the total amount of monomers in the water-soluble polymer is less than 0.1 mol %.
[6] The polishing composition according to any one of the above [1] to [5], further comprising a pH adjuster.
[7] The polishing composition according to any one of the above [1] to [6], further comprising abrasive grains and a pH adjuster, wherein the abrasive grains comprise silica, and wherein the pH adjuster comprises a basic compound.
[8] The polishing composition according to any one of the above [1] to [7], further comprising a surfactant.
[9] The polishing composition according to any one of the above [1] to [8], further comprising a surfactant, wherein the surfactant comprises at least one selected from polyoxyethylene alkyl ethers and copolymers having an oxyethylene-oxypropylene structure.
[10] The polishing composition according to any one of the above [1] to [9], further comprising a surfactant, wherein the mass ratio of the water-soluble polymer and the surfactant is 1:0.01 to 1:200.
[11] The polishing composition according to any one of the above [1] to [10], further comprising a solvent at least containing water, wherein the concentration of the water-soluble polymer in the polishing composition is 1 ppm or more.
[12] The polishing composition according to any one of the above [1] to [11], further comprising a solvent at least containing water, wherein the polishing composition has a solid content of 0.01 mass % or more.
[13] A method for producing a polished product, comprising the step of polishing the surface of a workpiece to be polished with the polishing composition according to anyone of the above [1] to [12].
[14] The method for producing a polished product according to the above [13], further comprising the step of diluting the polishing composition with a solvent at least containing water, wherein the polishing step uses the diluted solution obtained in the dilution step to polish the surface of the workpiece.
[15] A method for reducing AFM roughness on a polished surface, comprising the step of polishing a surface of a workpiece to be polished with the polishing composition of any one of the above [1] to [12].
[16] A method for reducing haze on a polished surface, comprising the step of polishing a surface of a workpiece to be polished with the polishing composition of any one of the above [1] to [12].

### Advantageous Effects of Invention

The present invention provides a novel polishing composition.

This composition can be used for polishing, in particular, semiconductor substrates such as silicon wafers, to achieve a reduced AFM roughness (in particular, long-wavelength roughness) on the polished surface, thereby enabling the production of a polished product with a high-quality surface. Another advantage is to enable efficient focusing during exposure in semiconductor device fabrication.

In addition, the composition can be used for polishing the aforementioned substrates to achieve a reduced haze on the polished surface, thereby enabling the production of a polished product with a high-quality surface.

Furthermore, the composition can be used to facilitate efficient fabrication of semiconductor devices etc.

The present invention provides a method for producing a polished product using the composition described above.

### DESCRIPTION OF EMBODIMENTS

### Composition

The composition of the present invention usually comprises a specific water-soluble polymer, which is described later. The composition of the present invention can be used, in particular, for polishing.

### Water-Soluble Polymer

The water-soluble polymer may comprise a vinyl alcohol-based resin (hereinafter sometimes referred to as vinyl alcohol-based resin (A)) of which a 4% aqueous solution has a viscosity of 15 mPa·s or more at 20° C.

### Vinyl Alcohol-Based Resin (A)

The vinyl alcohol-based resin is usually a polyvinyl alcohol-based resin (sometimes referred to as a PVA-based resin, PVA, etc.) and is a saponified product of a vinyl ester-based polymer (a polymer composed of a vinyl ester as at least a polymerization component).

The vinyl ester (vinyl ester monomer) is not particularly limited, and examples include fatty acid vinyl esters [e.g., C₁₋₃₀ fatty acid vinyl esters (e.g., C₁₋₁₆ alkanoic acid vinyl esters) such as vinyl formate, vinyl acetate, vinyl propionate, vinyl butyrate, vinyl caprylate, vinyl versatate, and vinyl monochloroacetate], and aromatic carboxylic acid vinyl esters [e.g., vinyl arenecarboxylates (e.g., C₇₋₁₂ arene carboxylic acid vinyl esters) such as vinyl benzoate].

A single kind of vinyl ester or a combination of two or more kinds of vinyl esters may be used.

The vinyl ester preferably at least comprises a fatty acid vinyl ester (e.g., C₁₋₁₀ alkanoic acid vinyl esters etc., such as vinyl formate, vinyl acetate, vinyl propionate, and vinyl butyrate). In particular, it is industrially preferable that the vinyl ester comprises vinyl acetate.

If necessary, the vinyl ester-based polymer may have an additional monomer unit (a monomer capable of copolymerizing with vinyl esters) (in other words, the vinyl ester-based polymer may be modified with an additional monomer).

The additional monomer is not particularly limited, and examples include, but are not limited to, alkyl vinyl ethers (e.g., C₁₋₃₀ alkyl vinyl ethers, preferably C₁₋₁₆ alkyl vinyl ethers, such as hexadecyl vinyl ether), epoxy group-containing vinyl monomers {e.g., vinyl glycidyl ethers (e.g., allyl glycidyl ether, (meth)acrylic glycidyl ether, 4-(meth)acrylamidophenyl glycidyl ether, 3-(meth)acrylamidophenyl glycidyl ether, N-glycidoxymethyl (meth)acrylamide, N-glycidoxyethyl (meth)acrylamide, N-glycidoxypropyl (meth)acrylamide, N-glycidoxybutyl (meth)acrylamide, and 4-(meth)acrylamidomethyl-2,5-dimethyl-phenylglycidyl ether), epoxy group-containing α-olefins (e.g., 1,2-epoxy-5-hexene, 1,2-epoxy-7-octene, 1,2-epoxy-9-decene, 8-hydroxy-6,7-epoxy-1-octene, and 8-acetoxy-6,7-epoxy-1-octene), N-(2,3-epoxy)propyl (meth)acrylamide, (meth)acrylamidopropyldimethyl(2,3-epoxy)propyl ammonium chloride, glycidyl (meth)acrylate, etc.}, α-olefins (e.g., ethylene, propylene, etc.), (meth)acrylic acid esters [e.g., (meth)acrylic acid alkyl esters such as methyl (meth)acrylate, ethyl (meth)acrylate, butyl (meth)acrylate, and 2-ethylhexyl (meth)acrylate; and diacetone (meth)acrylate], unsaturated amides [e.g., (meth)acrylamide, diacetone (meth)acrylamide, N-methylolacrylamide, etc.], unsaturated acids {e.g., unsaturated acids [e.g., (meth)acrylic acid, crotonic acid, maleic acid, itaconic acid, fumaric acid, etc.], unsaturated acid esters [unsaturated acid esters other than (meth)acrylic acid esters, e.g., alkyl (methyl, ethyl, propyl, etc.) esters etc.], unsaturated acid anhydrides (maleic anhydride etc.), salts of unsaturated acids [e.g., alkali metal salts (e.g., sodium salts, potassium salts, etc.), ammonium salts, etc.], etc.}, glycidyl group-containing monomers [e.g., allyl glycidyl ethers, glycidyl (meth)acrylate, etc.], sulfonic group-containing monomers (e.g., 2-acrylamide-2-methylpropane sulfonic acid, salts thereof, etc.), phosphate group-containing monomers [e.g., acid phosphoxy ethyl (meth)acrylate, acid phosphoxy propyl (meth)acrylate, etc.], allyl alcohols, diacetone (meth)acrylamide, etc.

A single kind of additional monomer or a combination of two or more kinds of additional monomers may be used.

The vinyl ester units and/or additional monomer units may be modified to the extent that such modification does not interfere with the effects of the present invention.

The vinyl ester units may be modified, for example, by acetalization, etherification, acetoacetylation, cationization, anionization (e.g., carboxyl group modification, sulfonic acid group modification, etc.), polyoxyalkylene modification (e.g., ethylene oxide group modification), etc.

The additional monomer units may be modified by, for example, a ring-opening reaction of an epoxy group (e.g., reaction of an epoxy group with a thiol).

The modification method is not particularly limited. For acetoacetylation of the vinyl ester units, for example, a vinyl alcohol-based resin can be reacted with a diketene.

The method for reacting a vinyl alcohol-based resin with a diketene is not particularly limited, and examples include the following: a vinyl alcohol-based resin is reacted directly with a gaseous or liquid diketene; an organic acid is pre-adsorbed onto a vinyl alcohol-based resin, and a gaseous or liquid diketene is then sprayed onto the resin under an inert gas atmosphere; and a mixture of an organic acid and a liquid diketene is sprayed onto a vinyl alcohol-based resin.

The ring-opening reaction of an epoxy group in the additional monomer unit can be performed, for example, by reacting an epoxy group-containing vinyl monomer unit with a thiol [e.g., a thiol having an amino group (such as the thiol described in U.S. Pat. No. 3,647,630) etc.] (e.g., the method described in U.S. Pat. No. 3,647,630, etc.).

A single kind of vinyl alcohol-based resin (A) or a combination of two or more kinds of vinyl alcohol-based resins (A) may be used.

The vinyl alcohol-based resin (A) may be a commercial product.

The method for producing the vinyl alcohol-based resin (A) is not particularly limited, and known methods, for example, saponification of a vinyl ester-based polymer, may be used.

The polymerization method for the vinyl ester-based polymer is not particularly limited, and examples include known polymerization methods such as bulk polymerization, solution polymerization, suspension polymerization, and emulsion polymerization. Among them, solution polymerization (e.g., solution polymerization using methanol as a solvent) is industrially preferred.

In the solution polymerization, known initiators such as peroxide initiators and azo initiators can be used, and the polymerization degree of the vinyl ester-based polymer can be adjusted by varying the feed ratio of the vinyl ester monomer and a solvent and the polymerization yield.

The method for saponifying the vinyl ester-based polymer can be a conventional saponification method using an alkaline or acid catalyst. In particular, industrially preferred is alcoholysis, which is performed by adding an alkali such as sodium hydroxide to a solution of the vinyl ester-based polymer in methanol or in a mixed solvent of methanol, water, methyl acetate, etc. and stirring the mixture.

After that, the obtained mass product, gelled product, or granular product is pulverized, and optionally, the alkali is neutralized; then the solid matter is separated from the liquid matter and dried to yield a PVA-based resin.

In the case of modifying a vinyl ester-based polymer, the timing of the modification is not particularly limited and may be before or after the saponification of the vinyl ester-based polymer.

Representative examples of the vinyl alcohol-based resin (A) include saponified products of vinyl ester-based polymers composed of a vinyl ester as at least a polymerization component.

The vinyl alcohol-based resin (A) may be modified (e.g., modified as described above) or may have a modifying group. For example, the vinyl alcohol-based resin (A) may be modified such that the vinyl ester units and/or additional monomer units therein are modified as described above, or may be composed of monomers having a modifying group.

The viscosity of a 4% aqueous solution of the vinyl alcohol-based resin (A) at 20° C. is usually 15 mPa·s or more (e.g., 18 mPa·s or more, 20 mPa·s or more, 22 mPa·s or more, 25 mPa·s or more, 30 mPa·s or more, 40 mPa·s or more, 50 mPa·s or more, 60 mPa·s or more, 70 mPa·s or more, 80 mPa·s or more, or 90 mPa·s or more), preferably 100 mPa·s or more (e.g., 110 mPa·s or more, 120 mPa·s or more, 130 mPa·s or more, or 140 mPa·s or more), more preferably 150 mPa·s or more (e.g., 160 mPa·s or more, 170 mPa·s or more, 180 mPa·s or more, or 190 mPa·s or more), and even more preferably 200 mPa·s or more (e.g., 210 mPa·s or more, 220 mPa·s or more, 230 mPa·s or more, 240 mPa·s or more, 250 mPa·s or more, 260 mPa·s or more, 270 mPa·s or more, 280 mPa·s or more, 290 mPa·s or more, or 300 mPa·s or more).

In the present invention, the viscosity of the 4% aqueous solution of the vinyl alcohol-based resin (A) at 20° C. may be relatively high because this facilitates the achievement of a reduced AFM roughness and haze on the polished surface of, in particular, semiconductor substrates such as silicon wafers.

In particular, when the saponification value of the vinyl alcohol-based resin (A) is 98.0 mol % or more (e.g., 98.0 to 99.9 mol %), the viscosity of a 4% aqueous solution of the vinyl alcohol-based resin (A) at 20° C. is, for example, 40 mPa·s or more (e.g., 50 mPa·s or more), and preferably 60 mPa·s or more (e.g., 70 mPa·s or more).

When the saponification value of the vinyl alcohol-based resin (A) is about 88 mol % (e.g., 85 to 90 mol %), the viscosity of a 4% aqueous solution of the vinyl alcohol-based resin (A) at 20° C. is, for example, 180 mPa·s or more (e.g., 190 mPa·s or more), preferably 200 mPa·s or more (e.g., 210 mPa·s or more), and more preferably 220 mPa·s or more (e.g., 230 mPa·s or more).

The upper limit of the viscosity of the 4% aqueous solution of the vinyl alcohol-based resin (A) at 20° C. is not particularly specified. For example, the viscosity is 3,000 mPa·s or less, or 2,500 mPa·s or less.

These upper and lower limits may be combined to set an appropriate range (e.g., 15 to 3,000 mPa·s, 60 to 3,000 mPa·s, 15 to 2,500 mPa·s, 20 to 2,500 mPa·s, 60 to 2,500 mPa·s, etc.) for the viscosity of the 4% aqueous solution of the vinyl alcohol-based resin (A) at 20° C. (the same applies to the others). All combinations of these upper and lower limits are applicable.

The viscosity of the 4% aqueous solution of the vinyl alcohol-based resin (A) at 20° C. can be measured, for example, by the method specified in JIS K 6726 (1994).

The saponification value of the vinyl alcohol-based resin (A) is not particularly limited and is, for example, 60 mol % or more (e.g., 70 mol % or more), preferably 80 mol % or more (e.g., 81 mol % or more, 82 mol % or more, 83 mol % or more, 84 mol % or more, or 85 mol % or more), and more preferably 90 mol % or more (e.g., 91 mol % or more, 92 mol % or more, 93 mol % or more, 94 mol % or more, 95 mol % or more, 96 mol % or more, 97 mol % or more, 98 mol % or more, or 99 mol % or more).

The upper limit of the saponification value is not particularly specified. For example, the saponification value is 99.9 mol % or less, 99.5 mol % or less, 99 mol % or less, 98 mol % or less, 97 mol % or less, 96 mol % or less, 95 mol % or less, etc.

These upper and lower limits may be combined to set an appropriate range (e.g., 80 to 99.9 mol % etc.) for the saponification value of the vinyl alcohol-based resin (A) (the same applies to the others). All combinations of these upper and lower limits are applicable.

The saponification value of the vinyl alcohol-based resin (A) can be measured, for example, by the method for measuring the saponification value specified in JIS K 6726.

The average polymerization degree of the vinyl alcohol-based resin (A) is not particularly limited and is, for example, 1,700 to 12,000, preferably 2,000 to 11,000, more preferably 3,000 to 10,000, and particularly preferably 4,000 to 9,000.

The average polymerization degree of the vinyl alcohol-based resin (A) can be measured, for example, by the method specified in JIS K 6726.

The composition of the present invention may further comprise an additional water-soluble polymer other than the vinyl alcohol-based resin (A).

Examples of the additional water-soluble polymer include, but are not limited to, vinyl alcohol-based resins that are not included in the scope of the vinyl alcohol-based resin (A), cellulose derivatives (e.g., methyl cellulose, ethyl cellulose, hydroxyethyl cellulose, hydroxypropyl cellulose, hydroxyethyl methyl cellulose, hydroxypropyl methyl cellulose, ethyl hydroxyethyl cellulose, and carboxymethyl cellulose), starch derivatives (e.g., pullulan and cyclodextrin), imine derivatives [e.g., poly(N-acylalkyleneimine)], polyvinylpyrrolidone resins, polyvinylcaprolactam resins, acrylic resins, polyacryloyl morpholine resins, polyoxyalkylenes (e.g., polyoxyethylene), etc.

A single kind of additional water-soluble polymer or a combination of two or more kinds of additional water-soluble polymers may be used.

The additional water-soluble polymer may also be modified as described above to the extent that such modification does not interfere with the effect of the present invention. The amount of monomers having an acid group (e.g., a carboxyl group) relative to the total amount of monomers in the additional water-soluble polymer (or monomers constituting the additional water-soluble polymer) is, for example, 5 mol % or less, or 2 mol % or less (e.g., less than 2 mol %, 1 mol % or less, less than 1 mol %, 0.5 mol % or less, less than 0.5 mol %, 0.1 mol % or less, less than 0.1 mol %, etc.).

In the modified vinyl alcohol-based resin (A), the amount of monomer structural units having a modifying group (or structural units having a modifying group) relative to the combined amount of vinyl ester (and vinyl alcohol) structural units and structural units having a modifying group is preferably less than 0.1 mol %, more preferably less than 0.01 mol %, and even more preferably less than 0.001 mol %.

In the cationically modified vinyl alcohol-based resin (A), the amount of structural units having a cationic group relative to the combined amount of vinyl ester (and vinyl alcohol) structural units and structural units having a cationic group is preferably less than 0.01 mol %, more preferably less than 0.001 mol %, and even more preferably 0.0005 mol % or less.

In the anionically modified vinyl alcohol-based resin (A), the amount of structural units having an anionic group relative to the combined amount of vinyl ester (and vinyl alcohol) structural units and structural units having an anionic group is preferably less than 0.1 mol %, more preferably 0.01 mol % or less, and even more preferably 0.001 mol % or less.

In the ethylene oxide-modified vinyl alcohol-based resin (A), the amount of structural units having an ethylene oxide group relative to the combined amount of vinyl ester (and vinyl alcohol) structural units and structural units having an ethylene oxide group is preferably 5 mol % or less, more preferably 3 mol % or less, and even more preferably 1 mol % or less.

### Surfactant

The composition of the present invention may further comprise a surfactant.

The use of the surfactant can improve the dispersion stability of the composition. The use of the surfactant facilitates the achievement of a reduced AFM roughness and haze on polished surfaces.

The molecular weight of the surfactant is preferably 1×10⁴ or less from the perspective of dispersibility of the composition and detergency performance on workpieces to be polished.

The lower limit of the molecular weight of the surfactant can be selected according to the type of surfactant etc. The molecular weight of the surfactant is, for example, 200 or more, and for the purpose of haze reduction etc., it is preferably 250 or more, more preferably 300 or more (e.g., 500 or more), even more preferably 2,000 or more, and particularly preferably 5,000 or more.

More specifically, the molecular weight of the surfactant is, for example, 200 to 10,000, preferably 250 to 10,000, and more preferably 300 to 10,000 (e.g., 2,000 to 10,000, or 5,000 to 10,000).

The molecular weight of the surfactant can be a weight-average molecular weight (Mw) determined by GPC (aqueous GPC, expressed on a polyethylene glycol equivalent basis) or a molecular weight calculated from the chemical formula of the surfactant.

The surfactant may be a water-soluble polymer having a molecular weight that falls within a range as exemplified above (e.g., an additional water-soluble polymer as exemplified above).

Specific examples of the surfactant include anionic surfactants and nonionic surfactants. Nonionic surfactants are preferred because of their low foaming tendency, ease of pH adjustment, etc.

The anionic surfactants include, for example, copolymers of multiple kinds of oxyalkylenes (e.g., diblock, triblock, random, or alternating copolymers of multiple kinds of oxy C₂₋₆ alkylenes, preferably oxy C₂₋₃ alkylenes), oxyalkylene polymers (e.g., polyethylene glycol, polypropylene glycol, polytetramethylene glycol, etc.), polyoxyalkylene adducts {e.g., polyoxy C₂₋₆ alkylene adducts, preferably polyoxy C₂₋₃ alkylene adducts such as polyoxyethylene adducts [e.g., polyoxyethylene alkyl ethers (e.g., polyoxyethylene propyl ether, polyoxyethylene butyl ether, polyoxyethylene pentyl ether, polyoxyethylene hexyl ether, polyoxyethylene octyl ether, polyoxyethylene-2-ethylhexyl ether, polyoxyethylene nonyl ether, polyoxyethylene decyl ether, polyoxyethylene isodecyl ether, polyoxyethylene tridecyl ether, polyoxyethylene lauryl ether, polyoxyethylene cetyl ether, polyoxyethylene stearyl ether, polyoxyethylene isostearyl ether, and polyoxyethylene oleyl ether), polyoxyethylene phenyl ether, polyoxyethylene alkyl phenyl ethers (e.g., polyoxyethylene octyl phenyl ether, polyoxyethylene nonyl phenyl ether, and polyoxyethylene dodecyl phenyl ether), polyoxyethylene styrenated phenyl ether, polyoxyethylene alkylamines (e.g., polyoxyethylene laurylamine, polyoxyethylene stearylamine, and polyoxyethylene oleylamine), polyoxyethylene alkylamides (e.g., polyoxyethylene stearylamide and polyoxyethylene oleylamide), polyoxyethylene fatty acid esters (e.g., polyoxyethylene monolaurate, polyoxyethylene monostearate, polyoxyethylene distearate, polyoxyethylene monooleate, and polyoxyethylene dioleate), polyoxyethylene glyceryl ether fatty acid esters, polyoxyethylene sorbitan fatty acid esters (e.g., polyoxyethylene sorbitan monolaurate, polyoxyethylene sorbitan monopalmitate, polyoxyethylene sorbitan monostearate, polyoxyethylene sorbitan monooleate, and polyoxyethylene sorbitan trioleate), polyoxyethylene sorbitol tetraoleate, polyoxyethylene castor oil, and polyoxyethylene hydrogenated castor oil]}, and acetylene glycol-based surfactants [e.g., alkylene oxide (e.g., ethylene oxide, etc.) adducts of acetylene glycol].

The copolymers of multiple kinds of oxyalkylenes include, for example, copolymers having an oxyethylene (EO) structure and an oxypropylene (PO) structure (copolymers having an EO-PO structure) {e.g., block copolymers of EO and PO [e.g., diblock copolymers of EO and PO, triblock copolymers of polyoxyethylene (PEO)-polyoxypropylene (PPO)-PEO, triblock copolymers of PPO-PEO-PPO, etc.], random copolymers of EO and PO, etc.}.

Among these nonionic surfactants, preferred are copolymers having an EO-PO structure, polyoxyethylene alkyl ethers, acetylene glycol-based surfactants, etc. Particularly preferred are block copolymers of EO and PO (in particular, triblock copolymers of PEO-PPO-PEO), random copolymers of EO and PO, polyoxyethylene alkyl ethers (e.g., polyoxyethylene decyl ether), etc.

The triblock copolymers of PEO-PPO-PEO are preferably polymers represented by the following general formula (2).

HO-(EO)a-(PO)b-(EO)c-H (2)

In the general formula (2), EO represents an oxyethylene unit (—CH₂CH₂O—), PO represents an oxypropylene unit (—CH₂CH(CH₃)O—) group, and a, b and c each represent an integer of 1 or more (typically 2 or more).

In the general formula (2), the sum of a and c is an integer preferably in the range of 2 to 1,000, more preferably in the range of 5 to 500, and even more preferably in the range of 10 to 200.

In the general formula (2), b is an integer preferably in the range of 2 to 200, more preferably in the range of 5 to 100, and even more preferably in the range of 10 to 50.

The molar ratio of EO to PO (EO/PO ratio) in a block or random copolymer of EO and PO is preferably greater than 1, more preferably 2 or greater, and even more preferably 3 or greater (e.g., 5 or greater) from the perspective of water solubility, detergency performance, etc.

The acetylene glycol-based surfactant used in the present invention can be, for example, a commercially available product of Surfynol 400 series manufactured by Nissin Chemical Co., Ltd.

A single kind of surfactant or a combination of two or more kinds of surfactants may be used.

The HLB value of the surfactant is not particularly limited and is, for example, 8 to 20, preferably 10 to 20, and more preferably 15 to 20.

### Abrasive Grains

The composition of the present invention may comprise abrasive grains.

The abrasive grains are not particularly limited, and examples include inorganic particles [e.g., inorganic oxides {e.g., metal oxides (e.g., alumina, cerium oxide, chromium oxide, titanium dioxide, zirconium oxide, magnesium oxide, manganese dioxide, zinc oxide, and bengalla), and semimetal oxides (e.g., silica)}, metal hydroxides [e.g., rare earth metal hydroxides (e.g., cerium hydroxide) and zirconium hydroxide], inorganic nitrides (e.g., silicon nitride and boron nitride), inorganic carbides (e.g., silicon carbide and boron carbide), inorganic carbonates {e.g., alkali metal carbonates (e.g., sodium carbonate and potassium carbonate), alkaline earth metal carbonates (e.g., calcium carbonate and barium carbonate), and other metal carbonates}, diamonds, etc.]; organic particles [e.g., polymers of unsaturated acids (e.g., poly(meth)acrylic acid), polymers of (meth)acrylic esters {e.g., poly(meth)acrylic acid alkyl esters (e.g., polymethyl methacrylate)}, polyacrylonitrile, etc.]; and organic-inorganic composite particles.

Among these abrasive grains, inorganic particles are preferred, inorganic oxides (e.g., metal oxides and semimetal oxides) are more preferred, and silicas (e.g., colloidal silica, fumed silica, and precipitated silica) are particularly preferred. Therefore, the abrasive grains may at least comprise silica. When the abrasive grains comprise silica, the amount of the silica in the abrasive grains is, for example, 50% by weight or more (e.g., 60% by weight or more), 70% by weight or more (80% by weight or more), 90% by weight or more (95% by weight or more, or 99% by weight or more), etc.

Among silicas, colloidal silica and fumed silica are preferred because they are less likely to generate scratches on the surface of workpieces to be polished and can be used to achieve a reduced haze on the polished surface. Colloidal silica is more preferred because of its low likelihood of generating scratches. High-purity colloidal silica is particularly preferred for preventing metal contamination.

A single kind of abrasive grains or a combination of two or more kinds of abrasive grains may be used.

The abrasive grains may be in any form without particular limitations. The abrasive grains may be in the form of primary particles, secondary particles, or a mixture of both; and are preferably in the form of particles containing at least secondary particles.

The average primary particle diameter D_{P1} of the abrasive grains is not particularly limited. From the perspective of polishing speed etc., the average primary particle diameter D_{P1} is, for example, 5 nm or more, preferably 10 nm or more, more preferably 15 nm or more, and even more preferably 20 nm or more.

In addition, the average primary particle diameter D_{P1} of the abrasive grains is preferably less than 100 nm, more preferably 50 nm or less, and even more preferably 40 nm or less for the purpose of haze reduction etc.

These upper and lower limits may be combined to set an appropriate range (e.g., 5 nm to 50 nm, 5 nm to 40 nm, etc.) for the average primary particle diameter D_{P1} of the abrasive grains (the same applies to the others).

The average primary particle diameter D_{P1} of the abrasive grains can be calculated, for example, based on the specific surface area S (m²/g) as measured by the BET method, using the formula of D_{P1}=2,720/S (nm).

The measurement of the specific surface area can be performed in any manner without particular limitations, for example, using a surface area measuring instrument, Flow Sorb II 2300 (trade name) manufactured by Micromeritics Instrument Corporation.

The average secondary particle diameter D_{P2} of the abrasive grains is not particularly limited. From the perspective of polishing speed etc., the average secondary particle diameter D_{P2} is, for example, 10 nm or more, and preferably 20 nm or more.

For the purpose of enhancing polishing performance etc., the average secondary particle diameter D_{P2} of the abrasive grains is preferably 30 nm or more, more preferably 35 nm or more, and particularly preferably 40 nm or more (e.g., more than 40 nm).

In addition, the average secondary particle diameter D_{P2} of the abrasive grains is, for example, less than 100 nm or less, preferably 90 nm or less, and more preferably 80 nm or less, so that the abrasive grains can easily be present in the polishing composition as particles of a size suitable for the purpose of microdefect reduction.

These upper and lower limits may be combined to set an appropriate range (e.g., 10 nm to 90 nm, 20 nm to 80 nm, etc.) for the average secondary particle diameter D_{P2} of the abrasive grains (the same applies to the others).

The average secondary particle diameter D_{P2} of the abrasive grains can be measured using a water dispersion of the abrasive grains (without any water-soluble polymer) by a laser diffraction scattering method, for example, using a particle size analyzer, the model UPA-UT151 manufactured by Nikkiso Co. Ltd.

The average secondary particle diameter D_{P2} of the abrasive grains may be equal to or greater than the average primary particle diameter D_{P1} (D_{P2}/D_{P1}≥1) or may be greater than D_{P1} (D_{P2}/D_{P1}>1).

The D_{P2}/D_{P1} ratio of the abrasive grains is preferably in the range of 1 to 3 from the perspective of polishing performance and smoothness on polished surfaces.

The shape (outline) of the abrasive grains is not particularly limited and may be spherical or non-spherical {e.g., a peanut shape (i.e., a peanut shell shape), a cocoon shape, a kompeito shape, or a rugby ball shape}.

The average value of the ratio of the major diameter/minor diameter of the primary particles of the abrasive grains (average aspect ratio) is not particularly limited. From the perspective of polishing speed etc., the average aspect ratio is preferably 1.0 or more, more preferably 1.05 or more, and even more preferably 1.1 or more.

In addition, the average aspect ratio of the abrasive grains is preferably 3.0 or less, more preferably 2.0 or less, and even more preferably 1.5 or less for reducing the risk of generating scratches etc.

The shape (outline) and average aspect ratio of the abrasive grains can be confirmed, for example, by electron microscopy. The specific procedure is, for example, as follows. While abrasive particles are observed under a scanning electron microscope (SEM), a predetermined number (e.g., 200) of particles whose shapes are individually recognizable are selected, and the minimum rectangle circumscribed to the image of each particle is drawn. For each rectangle drawn for each particle image, the length of the long side (the value of the major diameter) is divided by the length of the short side (the value of the minor diameter) to calculate the ratio of the major diameter to the minor diameter (aspect ratio). The average aspect ratio can be obtained by arithmetically averaging the aspect ratios of the above predetermined number of particles.

### pH Adjuster

The composition of the present invention may comprise a pH adjuster.

The pH adjuster is preferably a basic compound because it can enhance chemical polishing performance on the surface of workpieces to be polished, increase polishing speed, and improve the dispersion stability of the composition.

The use of basic compounds can increase the pH of the composition.

Examples of the basic compound include nitrogen-containing organic or inorganic basic compounds [e.g., quaternary ammonium hydroxides or their salts (e.g., tetramethylammonium hydroxide, tetraethylammonium hydroxide, tetrabutylammonium hydroxide, etc.), ammonia, amines {e.g., methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, guanidine, etc.}, azoles (e.g., anhydrous piperazine, piperazine hexahydrate, 1-(2-aminoethyl)piperazine, N-methylpiperazine, imidazole, triazole, etc.), etc.], hydroxides of alkali metals or alkaline earth metals (e.g., potassium hydroxide, sodium hydroxide, etc.), carbonates (e.g., ammonium carbonate, potassium carbonate, sodium carbonate, etc.), and hydrogen carbonates (e.g., ammonium hydrogen carbonate, potassium hydrogen carbonate, sodium hydrogen carbonate, etc.).

Among these basic compounds, ammonia, alkali metal hydroxides (e.g., potassium hydroxide, sodium hydroxide, etc.), quaternary ammonium hydroxides or their salts (e.g., tetramethylammonium hydroxide, tetraethylammonium hydroxide, etc.), carbonates (e.g., ammonium carbonate, potassium carbonate, sodium carbonate, etc.), hydrogen carbonates (e.g., ammonium hydrogen carbonate, potassium hydrogen carbonate, sodium hydrogen carbonate, etc.), etc., are preferred because they can increase polishing speed etc. More preferred are ammonia, potassium hydroxide, sodium hydroxide, tetramethylammonium hydroxide, and tetraethylammonium hydroxide; even more preferred are ammonia and tetramethylammonium hydroxide; and particularly preferred is ammonia.

A single kind of basic compound or a combination of two or more kinds of basic compounds may be used.

### Solvent

The composition of the present invention may comprise a solvent.

The solvent is not particularly limited, and examples include water and organic solvents (e.g., lower alcohols, lower ketones, etc.).

It is preferable that the solvent at least contains water.

The amount of the water in the solvent is preferably 90% by volume or more, and more preferably 95% by volume or more (e.g., 99 to 100% by volume).

The water is preferably ion-exchanged water (deionized water), pure water, ultrapure water, distilled water, etc.

A total amount of transition metal ions in the water is preferably as little as 100 ppb or less in order to minimize the interference with the actions of the other components in the composition.

The water may be a water that has been highly purified, for example, by removal of ionic impurities using ion exchange resins, removal of foreign matter using filters, distillation, or other processes.

### Additional Components

The composition may comprise an additional component in addition to the above components (the water-soluble polymer, abrasive grains, pH adjuster, surfactant, and solvent).

The additional component is not particularly limited and is, for example, a chelating agent, an organic acid, an organic acid salt, an inorganic acid, an inorganic acid salt, a preservative, a fungicide, and another additive.

Examples of the chelating agent include aminocarboxylic acid chelating agents and organic phosphonic acid chelating agents.

The aminocarboxylic acid chelating agents include ethylenediamine tetraacetic acid, sodium ethylenediamine tetraacetate, nitrilotriacetic acid, sodium nitrilotriacetate, ammonium nitrilotriacetate, hydroxyethyl ethylenediamine triacetic acid, sodium hydroxyethyl ethylenediamine triacetate, diethylenetriamine pentaacetic acid, sodium diethylenetriamine pentaacetate, triethylenetetramine hexaacetic acid, and sodium triethylenetetramine hexaacetate.

The organic phosphonic acid chelating agents include 2-aminoethylphosphonic acid, 1-hydroxyethylidene-1,1-diphosphonic acid, aminotri(methylenephosphonic acid), ethylenediamine tetrakis(methylenephosphonic acid), diethylenetriamine penta(methylenephosphonic acid), ethane-1,1-diphosphonic acid, ethane-1,1,2-triphosphonic acid, ethane-1-hydroxy-1,1-diphosphonic acid, ethane-1-hydroxy-1,1,2-triphosphonic acid, ethane-1,2-dicarboxy-1,2-diphosphonic acid, methane hydroxyphosphonic acid, 2-phosphonobutane-1,2-dicarboxylic acid, 1-phosphonobutane-2,3,4-tricarboxylic acid, and α-methylphosphonosuccinic acid.

Among these chelating agents, organic phosphonic acid chelating agents are preferred, and ethylenediamine tetrakis(methylenephosphonic acid), diethylenetriamine penta(methylenephosphonic acid), etc. are particularly preferred.

Examples of the organic acid include fatty acids (e.g., formic acid, acetic acid, propionic acid, etc.), aromatic carboxylic acids (e.g., benzoic acid, phthalic acid, etc.), citric acid, oxalic acid, tartaric acid, malic acid, maleic acid, fumaric acid, succinic acid, organic sulfonic acid, and organic phosphonic acid.

Examples of the organic acid salt include alkali metal salts of organic acids (e.g., sodium salts, potassium salts, etc.) and ammonium salts of organic acids.

Examples of the inorganic acid include sulfuric acid, nitric acid, hydrochloric acid, and carbonic acid.

Examples of the inorganic acid salt include alkali metal salts of inorganic acids (e.g., sodium salts, potassium salts, etc.) and ammonium salts of inorganic acids.

Examples of the preservative and fungicide include isothiazoline compounds, paraoxybenzoic esters, and phenoxyethanol.

A single kind of additional component or a combination of two or more kinds of additional components may be used.

### Modes of Composition

The composition may be directly used as a polishing solution. Alternatively, the composition may be diluted with a solvent (e.g., diluted at a dilution factor as described later) and used as a polishing solution. Further details are described later.

That is, the composition may be a less concentrated composition (a polishing solution) or a highly concentrated composition (a polishing concentrate).

The highly concentrated composition may be a concentrate of a less concentrated composition.

The amount of the water-soluble polymer in the composition (the proportion of the water-soluble polymer to the whole of the composition) is not particularly limited and is, for example, 1 ppm or more on amass basis. For the purpose of haze reduction etc., it is preferably 3 ppm or more on a mass basis, and more preferably 5 ppm or more (e.g., 10 ppm or more) on a mass basis.

In addition, the amount of the water-soluble polymer in the composition is preferably 1,000 ppm or less on a mass basis, and more preferably 500 ppm or less (e.g., 300 ppm or less) on a mass basis from the perspective of polishing speed etc.

These upper and lower limits may be combined to set an appropriate range for the amount of the water-soluble polymer in the composition. More specifically, the amount of the water-soluble polymer in the composition is, for example, 1 ppm to 1,000 ppm, preferably 3 ppm to 500 ppm, and more preferably 5 ppm to 300 ppm.

The amount of the water-soluble polymer, for example, in a highly concentrated composition, can be set according to the dilution factor etc. and is not particularly limited. The amount of the water-soluble polymer in the highly concentrated composition is, for example, 1,000 ppm or more on a mass basis, preferably 1,500 ppm or more on a mass basis, or 2,000 ppm or more on a mass basis.

In addition, the amount of the water-soluble polymer in the highly concentrated composition is preferably 20,000 ppm or less on a mass basis, and more preferably 10,000 ppm or less on a mass basis.

These upper and lower limits may be combined to set an appropriate range for the amount of the water-soluble polymer in the highly concentrated composition. More specifically, the amount of the water-soluble polymer in the highly concentrated composition is, for example, 1,000 ppm to 20,000 ppm, preferably 1,500 ppm to 10,000 ppm, and more preferably 2,000 ppm to 5,000 ppm.

In the case where the composition comprises abrasive grains, the amount of the abrasive grains in the composition (the proportion of the abrasive grains to the whole of the composition) is not particularly limited and is, for example, 0.01 mass % or more, preferably 0.05 mass % or more, and more preferably 0.1 mass % or more (e.g., 0.15 mass % or more). A greater amount of the abrasive grains can result in a higher polishing speed.

In addition, the amount of the abrasive grains in the composition is, for example, 10 mass % or less, preferably 7 mass % or less, and more preferably 5 mass % or less for the purpose of achieving a reduced haze on polished surfaces.

These upper and lower limits may be combined to set an appropriate range for the amount of the abrasive grains in the composition. More specifically, the amount of the abrasive grains in the composition is, for example, 0.01 mass % to 10 mass %, preferably 0.05 mass % to 7 mass %, and more preferably 0.1 mass % to 5 mass %.

The amount of the abrasive grains, for example, in a highly concentrated composition, can be set according to the dilution factor etc. and is not particularly limited. The amount of the abrasive grains in the highly concentrated composition is, for example, 0.2 mass % or more, preferably 1 mass % or more, and more preferably 2 mass % or more.

In addition, the amount of the abrasive grains in the highly concentrated composition is, for example, 50 mass % or less, preferably 20 mass % or less, and more preferably 10 mass % or less.

These upper and lower limits may be combined to set an appropriate range for the amount of the abrasive grains in the highly concentrated composition. More specifically, the amount of the abrasive grains in the highly concentrated composition is, for example, 0.2 mass % to 50 mass %, 1 mass % to 20 mass %, or 2 mass % to 10 mass %.

In the case where the composition comprises a pH adjuster, the amount of the pH adjuster in the composition (the proportion of the pH adjuster to the whole of the composition) is not particularly limited. From the perspective of polishing speed etc., the amount of the pH adjuster in the composition is, for example, 1 ppm or more, and preferably 5 ppm or more.

In addition, the amount of the pH adjuster in the composition is, for example, less than 1000 ppm, and preferably less than 500 ppm for the purpose of haze reduction etc.

These upper and lower limits may be combined to set an appropriate range for the amount of the pH adjuster in the composition. More specifically, the amount of the pH adjuster in the composition is, for example, 1 ppm or more and less than 1,000 ppm, or 5 ppm or more and less than 500 ppm.

The amount of the pH adjuster, for example, in a highly concentrated composition, can be set according to the dilution factor etc. and is not particularly limited. The amount of the pH adjuster in the highly concentrated composition is, for example, 20 ppm or more, and preferably 100 ppm or more.

In addition, the amount of the pH adjuster in the highly concentrated composition is, for example, less than 20,000 ppm, and preferably less than 10,000 ppm.

These upper and lower limits may be combined to set an appropriate range for the amount of the pH adjuster in the highly concentrated composition. More specifically, the amount of the pH adjuster in the highly concentrated composition is, for example, 20 ppm or more and less than 20,000 ppm, and preferably 100 ppm or more and less than 10,000 ppm.

In the case where the composition comprises a surfactant, the amount of the surfactant in the composition (the proportion of the surfactant to the whole of the composition) is not particularly limited. For the purpose of reducing AFM roughness and haze, the amount of the surfactant in the composition is, for example, 0.1 ppm or more, preferably 0.5 ppm or more, more preferably 1 ppm or more (e.g., 3 ppm or more), and even more preferably 5 ppm or more (e.g., 10 ppm or more).

In addition, the amount of the surfactant in the composition is, for example, 1,000 ppm or less, preferably 500 ppm or less (e.g., 300 ppm or less), and more preferably 100 ppm or less from the perspective of polishing speed etc.

These upper and lower limits may be combined to set an appropriate range for the amount of the surfactant in the composition. More specifically, the amount of the surfactant in the composition is, for example, 0.1 ppm to 1,000 ppm, preferably 0.5 ppm to 500 ppm, and more preferably 1 ppm to 100 ppm.

The amount of the surfactant, for example, in a highly concentrated composition, can be set according to the dilution factor etc. and is not particularly limited. The amount of the surfactant in the highly concentrated composition is, for example, 2 ppm or more, preferably 10 ppm or more, more preferably 20 ppm or more, and even more preferably 100 ppm or more.

In addition, the amount of the surfactant in the highly concentrated composition is, for example, 20,000 ppm or less, preferably 10,000 ppm or less, and more preferably 2,000 ppm or less.

These upper and lower limits may be combined to set an appropriate range for the amount of the surfactant in the highly concentrated composition. More specifically, the amount of the surfactant in the highly concentrated composition is, for example, 2 ppm to 20,000 ppm, preferably 10 ppm to 10,000 ppm, and more preferably 20 ppm to 2,000 ppm.

The solid content of the composition is not particularly limited and is, for example, 0.01 mass % or more, preferably 0.01 mass % to 50 mass %, and more preferably 0.05 mass % to 40 mass %.

The solid content of the composition, for example, in a highly concentrated composition, can be set according to the dilution factor etc. and is not particularly limited. The solid content of the highly concentrated composition is, for example, 1 mass % or more, preferably 2 mass % to 50 mass %, and more preferably 5 mass % to 25 mass %.

The solid content can be expressed as a mass percentage of dry matter residue in the composition after drying the composition at 105° C. for 24 hours.

In the case where the composition comprises an additional component, the amount of the additional component in the composition (the proportion of the additional component to the whole of the composition) is not particularly limited and is, for example, 0.01 to 30 mass %, preferably 0.01 to 20 mass %, and more preferably 0.01 to 10 mass %.

The amount of the additional component, for example, in a highly concentrated composition, can be set according to the dilution factor etc. and is not particularly limited. The amount of the additional component in the highly concentrated composition is, for example, 0.2 to 60 mass %, preferably 0.2 to 40 mass %, and more preferably 0.2 to 20 mass %.

In the case where the composition comprises abrasive grains, the ratio of the water-soluble polymer and the abrasive grains in the composition is not particularly limited. The mass ratio of the water-soluble polymer:the abrasive grains is, for example, 10:1 to 1:1,000, preferably 5:1 to 1:500, and more preferably 1:1 to 1:100.

In the case where the composition comprises a surfactant, the ratio of the water-soluble polymer and the surfactant in the composition is not particularly limited. The mass ratio of the water-soluble polymer:the surfactant is, for example, 1:0.01 to 1:200, and preferably 1:0.01 to 1:100 (e.g., 1:0.01 to 1:20, more preferably 1:0.05 to 1:15, and particularly preferably 1:0.1 to 1:10).

The zeta potential of the composition is, for example, −0 mV or less, preferably −5 mV or less, and more preferably −10 mV or less for the purpose of preventing abrasive grains from agglomerating. In addition, the zeta potential of the composition is, for example, −100 mV or more, preferably −90 mV or more, and more preferably −80 mV or more from the perspective of polishing speed.

The zeta potential of the composition can be measured using, for example, an ultrasonic zeta potential measuring instrument, DT-1202 manufactured by Dispersion Technology, Inc.

### Method for Producing the Composition

The method for producing the composition of the present invention is not particularly limited. For example, the components to be combined into the composition may be mixed together. Mixing may be performed at room temperature or with heating.

Mixing may be performed with stirring, optionally using a mixing device (e.g., a blade stirrer, an ultrasonic disperser, a homomixer, etc.).

The components may be added in any order without particular limitations. For example, the components may be mixed all at once or sequentially in a predetermined order.

During the production process of the composition, filtration may be performed.

Filtration may be filtering the components separately before mixing or filtering a mixture of the components.

The filtration method is not particularly limited and may use a filter, for example.

Filtration may be circulating filtration, etc.

### Polishing

The surface of a workpiece to be polished can be polished with the composition of the present invention to produce a polished product.

The surface to be polished may be either both sides or one side of the workpiece.

In polishing both sides of the workpiece, both sides may be polished simultaneously or one after another.

A preferable embodiment of the method for polishing a workpiece to be polished using the composition of the present invention (a method for producing a polished product) will be described below.

The materials of the workpiece to be polished include, for example, metals or semimetals such as silicon, aluminum, nickel, tungsten, copper, tantalum, titanium, and stainless steel, or their alloys; glass-like materials such as quartz glass, aluminosilicate glass, and glass-like carbon; ceramic materials such as alumina, silica, sapphire, silicon nitride, tantalum nitride, and titanium carbide; compound semiconductor substrate materials such as silicon carbide, gallium nitride, and gallium arsenide; and resin materials such as polyimide resin.

Among these materials, silicon is preferably contained in the workpiece to be polished (e.g., monocrystalline silicon substrates).

The workpiece to be polished may be composed of multiple materials.

The workpiece to be polished may have a coat formed on the substrate, but in the present invention, it is preferable to polish the substrate itself. The coat can be, for example, a polysilicon coat, a nitride coat, an oxide coat, etc. The thickness of the coat is, for example, more than 100 nm.

The surface to be polished may be a partially oxidized surface of the substrate (e.g., a natural oxide coat of 100 nm or less in thickness).

The shape of the workpiece to be polished is not particularly limited. For example, it is preferably a planar or polyhedral shape, which has a flat surface.

The polishing solution used for polishing may be the composition as it is or a diluted solution of the composition in a solvent.

The solvent for dilution can be a solvent as exemplified above and is preferably a solvent that at least contains water (an aqueous solvent). The solvent for dilution may be the same as or different from the solvent comprised in the composition of the present invention (in terms of the type of solvent or, when the solvent is a mixed solvent, the mixing ratio of the components).

The dilution factor is, for example, about 2 to 100 (e.g., about 5 to 50, or about 20 to 50), preferably 10 to 30, and more preferably 15 to 25 on a volume basis.

The polishing solution may be a pH-adjusted solution prepared with a pH adjuster as exemplified above.

The pH of the polishing solution can be selected according to the saponification value of the vinyl alcohol-based resin, the type of abrasive grains, etc. and is not particularly limited. The pH of the polishing solution is, for example, 8.0 to 12.0 (e.g., 9.0 to 11.0), or 5.0 to 9.0 (e.g., 6.0 to 8.0). The pH ranges described above are, for example, particularly preferably applicable for polishing solutions used for polishing silicon wafers (e.g., polishing solutions used for final polishing).

The polishing solution is applied to a workpiece to be polished, and the workpiece can be polished by the usual method.

The composition of the present invention is particularly suitable for use in polishing semiconductor substrates (particularly, silicon wafers).

The polishing step in which the composition is used is not particularly limited. For example, the composition is particularly suitable for use in the final polishing step or preceding polishing steps for silicon wafers.

The term “final polishing” usually refers to the last polishing step in the production process of the product of interest (i.e., a step after which no further polishing is performed). The composition of the present invention is effective, for example, for use in polishing silicon wafers that have been processed through preceding steps to have a surface roughness of 0.01 nm to 100 nm (typically for use in final polishing or in polishing immediately prior to final polishing), and is particularly suitable for use in final polishing.

For example, in the case of final polishing of a silicon wafer, a silicon wafer that has undergone a lapping step and primary and secondary polishing steps is set in a commonly used polishing machine, and a polishing solution is applied to the surface of the silicon wafer (the surface to be polished) through the polishing pad of the polishing machine. In an example, while the polishing solution is continuously supplied, the polishing pad is moved (e.g., rotationally) relative to the silicon wafer with the polishing pad pressed against the silicon wafer.

### Cleaning

The polished product obtained as described above may be subjected to cleaning.

Cleaning can be performed, for example, using a cleaning solution.

The cleaning solution is not particularly limited. For example, the SC-1 cleaning solution (a mixture of ammonium hydroxide (NH₄OH), hydrogen peroxide (H₂O₂), and water (H₂O) can be used for polished semiconductor substrates.

The temperature of the cleaning solution can be, for example, room temperature to about 90° C.

### Polished Product

The present invention also includes a polished product having a polished surface as described below.

The polished surface of the polished product has a root-mean-square (Sq) of preferably less than 0.030 nm, more preferably less than 0.028 nm as measured in a field of view of 30×30 μm² using an atomic force microscope.

The lower limit of the root mean square height (Sq) is not particularly specified. For example, Sq is 0.005 nm or more, 0.01 nm or more, etc.

The root-mean-square height (Sq) can be measured by the method described in the section “Examples” below.

The haze on the polished surface of the polished product is, for example, 0.3 ppm or less (e.g., less than 0.3 ppm), preferably 0.25 ppm or less (e.g., less than 0.25 ppm, or 0.01 ppm to 0.25 ppm), more preferably 0.20 ppm or less (e.g., less than 0.20 ppm, or 0.01 ppm to 0.20 ppm), particularly preferably 0.15 ppm or less (e.g., less than 0.15 ppm, or 0.01 ppm to 0.15 ppm), and most preferably 0.10 ppm or less (e.g., less than 0.10 ppm, or 0.01 ppm to 0.10 ppm).

The haze can be measured, for example, by the method described in the section “Examples” below.

In order to obtain polished products having a polished surface as described above, for example, workpieces to be polished are polished with a polishing composition comprising a certain water-soluble polymer and then cleaned.

The water-soluble polymer is, for example, a water-soluble polymer having a relatively high viscosity (e.g., 15 mPa·s or more as measured in a 4% aqueous solution at 20° C.).

For example, vinyl alcohol-based resins are suitable for use as the water-soluble polymer. The use of the vinyl alcohol-based resin (A) described above in a polishing composition enables efficient production of a polished product having a polished surface as described above.

### EXAMPLES

Hereinafter, the present invention will be described in more detail by examples, but the present invention is not limited thereto.

In the following examples, “part(s)” and “%” refer to part(s) by mass and a percent by mass unless otherwise specified.

The physical properties of PVAs in the examples were evaluated by the following methods.

(1) Viscosity of 4% aqueous solution:

Measured according to JIS K 6726 (1994)

(2) Saponification value:

Measured according to JIS K 6726 (1994).

### Synthesis Examples 1 to 4

PVA-1 to PVA-4 shown in Table 1 were obtained as described in Production Example 1 of JP-A 2013-153149, except that polymerization conditions (feed ratio, temperature, pressure, polymerization time, etc.) and saponification conditions (temperature, saponification time, etc.) were changed so that the PVAs would have their respective 4% solution viscosities and saponification values as shown in Table 1.

### Example 1

To a 1% aqueous solution of colloidal silica having an average primary particle diameter of 35 nm (abrasive grains), a 29% aqueous solution of ammonia (NH₃, basic compound) was added to prepare a colloidal silica dispersion adjusted to pH 10.0. To this colloidal silica dispersion, PVA-1 (PVA) was added at a final concentration of 100 ppm to obtain a composition (polishing solution). The silica content of the composition was 1%.

### Example 2

A composition was obtained in the same manner as in Example 1, except that a copolymer having an EO-PO structure (Wako Pure Chemical Industries, polyoxyethylene polyoxypropylene glycol (160E.O.) (30P.O.)) was added at a final concentration of 10 ppm to the colloidal silica dispersion.

### Example 3

A composition was obtained in the same manner as in Example 1, except that the PVA was changed to PVA-2.

### Example 4

A composition was obtained in the same manner as in Example 1, except that the PVA was changed to PVA-3.

### Example 5

A composition was obtained in the same manner as in Example 1, except that a copolymer having an EO-PO structure (Wako Pure Chemical Industries, polyoxyethylene polyoxypropylene glycol (160E.O.) (30P.O.)) was added at a final concentration of 10 ppm to the colloidal silica dispersion and that the PVA was changed to PVA-3.

### Example 6

A composition was obtained in the same manner as in Example 1, except that the PVA was changed to PVA-4.

### Example 7

A composition was obtained in the same manner as in Example 1, except that a copolymer having an EO-PO structure (Wako Pure Chemical Industries, polyoxyethylene polyoxypropylene glycol (160E.O.) (30P.O.)) was added at a final concentration of 10 ppm to the colloidal silica dispersion and that the PVA was changed to PVA-4.

### Example 8

A composition was obtained in the same manner as in Example 1, except that PVA-6, which was obtained by mixing the PVA-4 and PVA-5 shown in Table 1 at PVA-4:PVA-5 (mass ratio)=48:52, was used as the PVA.

### Comparative Example 1

A composition was obtained in the same manner as in Example 1, except that polyvinylpyrrolidone (Wako Pure Chemical Industries, polyvinylpyrrolidone K90) was used as the water-soluble polymer.

### Silicon Wafer Polishing

The surfaces of silicon wafers were polished under the conditions shown below using the polishing solutions prepared in the examples described above.

The silicon wafers used were single-crystal silicon wafers having a diameter of 300 mm, a P-type conductivity, a crystal orientation <100>, a resistivity of 0.1 to 100 Ω·cm.

Polishing evaluations were performed at two stages: preliminary polishing to make the entire surface uniform and finish polishing with the above compositions using a single-wafer polishing machine, the model PNX-332B, manufactured by Okamoto Machine Tool Works, Ltd.

### Preliminary Polishing Conditions

Polishing cloth: Non-woven cloth
Polishing solution: Colloidal silica solution adjusted to pH 11 with KOH
Polishing load: 30 kPa
Plate rotation speed: 50 rpm
Head rotation speed: 50 rpm
Polishing time: 3 min.

### Finish Polishing Conditions

Polishing cloth: Suede
Polishing load: 15 kPa
Plate rotation speed: 30 rpm
Head rotation speed: 30 rpm
Polishing time: 3 min.

### Cleaning

After polishing, silicon wafers were cleaned with a mixture of NH₄OH, H₂O₂, and ultrapure water (SC1) (volume ratio of NH₄OH:H₂O₂:ultrapure water=1:3:30).

### AFM Roughness Measurement

The surfaces of the silicon wafers after cleaning were evaluated by atomic force microscopy (AFM). The observation was made at three points with coordinates (0 mm, 0 mm), (75 mm, 0 mm), and (145 mm, 0 mm), and the field of view was 30×30 μm² in each point. For roughness parameters, after slope correction in the X and Y directions, root-mean-square height (Sq) was calculated, and the average of the three point measurements was used as an evaluation index. The results were evaluated on a three-level scale as follows.

A: less than 0.028 nm
B: 0.028 nm or more and less than 0.030 nm
C: 0.030 nm or more

The results are shown in Table 1.

### Haze Measurement

The haze (ppm) on the surfaces of the silicon wafers after cleaning was measured using a wafer inspection system manufactured by KLA Tencor, trade name “SP3”, in a DWO mode. The results of the measurements were evaluated on a four-level scale as follows.

A: less than 0.10 ppm
B: 0.10 ppm or more and less than 0.20 ppm
C: 0.20 ppm or more and less than 0.30 ppm
D: 0.30 ppm or more

The evaluation results for the examples and comparative examples are shown in Table 1.

TABLE 1

| | Water-soluble polymer | | | | | |
|---|---|---|---|---|---|---|
| | | 4% | | | | |
| | | aqueous | | | Evaluation | |
| | | solution | Saponifi- | | results | |
| | | viscosity | cation | | AFM | |
| | | (mPa · s | value | Amount | rough- | |
| | PVA | @20° C.) | (mol %) | (ppm) | ness | Haze |
| Example 1 | PVA-1 | 226.1 | 99.3 | 100 | B | B |
| Example 2 | PVA-1 | 226.1 | 99.3 | 100 | A | A |
| | EOPO | | | 10 | | |
| Example 3 | PVA-2 | 1400 | 89.7 | 100 | A | B |
| Example 4 | PVA-3 | 2450 | 99.0 | 100 | A | A |
| Example 5 | PVA-3 | 2450 | 99.0 | 100 | A | A |
| | EOPO | | | 10 | | |
| Example 6 | PVA-4 | 28.9 | 98.3 | 100 | B | B |
| Example 7 | PVA-4 | 28.9 | 98.3 | 100 | A | A |
| | EOPO | | | 10 | | |
| Example 8 | PVA-6 | 15.3 | 98.8 | 100 | B | B |
| Comparative | PVP | | | 100 | C | B |
| Example 1 | | | | | | |

As shown in Table 1, the AFM roughness on the polished surface was lower across all the examples.

In addition, the haze on the polished surface was lower across all the examples.

### INDUSTRIAL APPLICABILITY

The composition of the present invention is very industrially useful because it can be used for polishing workpieces to achieve, for example, a reduced AFM roughness on the polished surface, thus enabling efficient processing of substrates that have a protective coat formed on their surface.

1. A polishing composition comprising a water-soluble polymer, wherein the water-soluble polymer at least comprises a vinyl alcohol-based resin, and wherein a 4% aqueous solution of the vinyl alcohol-based resin has a viscosity of 15 mPa·s or more at 20° C.

2. The polishing composition according to claim 1, wherein the water-soluble polymer has a saponification value of 80 to 99.9 mol %.

3. The polishing composition according to claim 1, further comprising abrasive grains.

4. The polishing composition according to claim 3, wherein the abrasive grains comprise silica.

5. The polishing composition according to claim 1, wherein the amount of monomers having an acid group relative to the total amount of monomers in the water-soluble polymer is less than 0.1 mol %.

6. The polishing composition according to claim 1, further comprising a pH adjuster.

7. The polishing composition according to claim 1, further comprising abrasive grains and a pH adjuster, wherein the abrasive grains comprise silica, and wherein the pH adjuster comprises a basic compound.

8. The polishing composition according to claim 1, further comprising a surfactant.

9. The polishing composition according to claim 1, further comprising a surfactant, wherein the surfactant comprises at least one selected from polyoxyethylene alkyl ethers and copolymers having an oxyethylene-oxypropylene structure.

10. The polishing composition according to claim 1, further comprising a surfactant, wherein the mass ratio of the water-soluble polymer and the surfactant is 1:0.01 to 1:200.

11. The polishing composition according to claim 1, further comprising a solvent at least containing water, wherein the concentration of the water-soluble polymer in the polishing composition is 1 ppm or more.

12. The polishing composition according to claim 1, further comprising a solvent at least containing water, wherein the polishing composition has a solid content of 0.01 mass % or more.

13. A method for producing a polished product, comprising the step of polishing the surface of a workpiece to be polished with the polishing composition according to claim 1.

14. The method for producing a polished product according to claim 13, further comprising the step of diluting the polishing composition with a solvent at least containing water, wherein the polishing step uses the diluted solution obtained in the dilution step to polish the surface of the workpiece.
